(19) United States
(12) Patent Application Publication
(10) Pub. No.: US 2025/0006655 A1
(43) Pub. Date: Jan. 2, 2025

(54) PHOTOALIGNMENT OF SEMICONDUCTOR STRUCTURES USING AN OPAQUE HARDMASK

(71) Applicant: Micron Technology, Inc., Boise, ID (US)

(72) Inventors: Shruthi Kumara Vadivel, Boise, ID (US); Harsh Narendrakumar Jain, Boise, ID (US); Lance David Williamson, Boise, ID (US); Kaveri Jain, Hyderabad (IN); Adam Lewis Olson, Boise, ID (US)

(21) Appl. No.: 18/750,247

(22) Filed: Jun. 21, 2024

Related U.S. Application Data
(60) Provisional application No. 63/523,567, filed on Jun. 27, 2023.

(51) Int. Cl. H01L 23/544; H01L 21/311

(52) U.S. Cl. CPC H01L 23/544; H01L 21/31144; H01L 2223/54426

(57) ABSTRACT

Aligning pillars of a three-dimensional NAND memory assembly can include forming a first pillar and a corresponding first pillar alignment feature in at least a portion of a first substrate stack. The alignment method can include depositing a second substrate stack on the first substrate stack, covering the first pillar alignment feature and the first pillar, and depositing a first masking layer on at least a portion of the second substrate stack. Illumination light can be used to illuminate a portion of the first masking layer. A reflected portion of the illumination light can indicate a location of the first pillar alignment feature corresponding to the first pillar. Particular wavelengths of the illumination light can be blocked or filtered by the first masking layer.

### PRIORITY APPLICATION

This application claims the benefit of priority to U.S. Provisional Application Ser. No. 63/523,567, filed Jun. 27, 2023, which is incorporated herein by reference in its entirety.

### TECHNICAL FIELD

The present disclosure relates to design and placement of alignment marks in semiconductor fabrication, particularly to fabrication of three-dimensional (3D) NAND memory.

### BACKGROUND

In the field of semiconductor manufacturing, integrated circuits are manufactured in a sequence of steps. The steps can include depositing and patterning various materials on a semiconductor wafer to form devices such as transistors, contacts, and other circuit components. For the final device (e.g., an integrated circuit chip) to function properly, the components must be aligned on each layer of the wafer, or stated differently, the components on each layer must all “line up” with each other. For example, in the fabrication of three-dimensional (3D) NAND memory, an important overlay relationship involves alignment between pillars in an upper portion of a substrate stack (an “upper deck”) and pillars in a lower portion of a substrate stack (a “lower deck”).

Overlay of the NAND pillars is particularly challenging due to systematic and sometimes random sources of variation arising from sequential etching, photolithography, and other film processing steps. A particular result of such process variation includes pillar tilt, which can be caused by a plasma gradient in the etch chamber. In some examples, different pillars of a semiconductor wafer exhibit differences in the magnitude and direction of the tilt.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIGS. 1A-1B illustrate examples of ideal and displaced pillar alignment of a three-dimensional (3D) NAND memory.

FIG. 1C illustrates an example of a pillar tilt signature as measured by a scanner.

FIG. 2A illustrates generally an example of a photoalignment system used to locate embedded structures.

FIG. 2B illustrates generally an example of a hardmask layer disposed over embedded pillar structures.

FIG. 3A illustrates generally an example of a photoalignment system used to locate embedded structures through a masking layer.

FIG. 3B illustrates generally an example of a patterned masking layer that is registered to one or more embedded structures.

FIG. 4 illustrates generally an example of a method that includes or uses an at least partially opaque hardmask layer to filter light from a photoalignment system.

FIG. 5 illustrates generally an example of a method that includes or uses topographical marks in hardmask layers with pillar alignment features to align pillars of a three-dimensional (3D) NAND memory assembly.

### DETAILED DESCRIPTION

Memory devices are provided as internal, semiconductor integrated circuits in computers or other electronic devices. Flash memory is utilized as non-volatile memory for a wide range of electronic applications. The memory density (e.g., the number of memory cells per memory die) of memory devices, such as non-volatile memory devices (e.g., NAND Flash memory devices) has been increased through implementation of vertical memory array (also referred to as a “three-dimensional (3D) memory array”) architectures.

A conventional vertical memory array includes a plurality of memory cell pillars extending through tiers formed from a stack of alternating substantially planar layers of dielectric materials and conductive materials. The memory cell pillars include a channel region positioned between a source region and a drain region, and the conductive layers in the tiers function as control gates in the completed device. The vertical configuration permits a greater number of electrical components (e.g., transistors) to be located in a unit of die area by building the array upwards (e.g., longitudinally, vertically) on a die, as compared to structures with conventional planar (e.g., two-dimensional) arrangements of electrical components.

To form the channel regions of the memory cell pillars, a first etch process is conducted to create, through a stack of tiers of alternating dielectric and nitride structures, a tapered high aspect ratio opening along a direction normal to a plane of a die or other support layer underlying the tier stack. The openings are subsequently filled with a conductive material to form the memory cell pillars, and the memory cell pillars are electrically connected with structures in the underlying die or support layer.

Increasing aspect ratios of the openings used to form the memory cell pillars, as well as increasing numbers of alternating dielectric and nitride layers in the stack, make precise control of the etch process increasingly difficult. The large number of layers in the stack also make formation of reliable electrical connections to the dies and support layers at the bottom of the openings increasingly challenging.

In some examples, 3D NAND can include multiple stacks (e.g., a top stack and a bottom stack), and each stack comprises several alternating dielectric and nitride layers. A bottom stack can include or use bottom stack pillars that extend through the layers of the bottom stack. A top stack can include or use top stack pillars that extend through the layers of the top stack. The top and bottom stack pillars can be aligned such that a bottom portion of a pillar in the top stack aligns with a top portion of a corresponding pillar in the bottom stack. Ideally, the respective top and bottom stack pillars are perfectly aligned so that the pillars of the top stack of the wafer are located vertically above corresponding pillars of the bottom stack. However, the pillars of a real 3D NAND structure can tilt or become angled during fabrication, which is a systematic source of variation in the fabrication of memory devices such as 3D NAND memory.

Pillar tilt is produced during an etch process, for example, due to localized plasma gradients in the etch chamber. The gradients correspond to different areas of a wafer undergoing processing, and thus different pillars, which can be distributed about the wafer, experience or exhibit differences in the magnitude and direction of tilt.

Pillar tilt can be problematic when pillars of multiple layers of substrate stacks require alignment. For example, a bottom stack can include one more bottom stack pillars that exhibit some degree of tilt. A top stack can be provided on the bottom stack, and top stack pillars can then be formed in the top stack, in alignment with the bottom stack pillars. The top stack pillar formation steps can include or use an alignment process. The alignment process can use an illumination light to detect, through the top stack, the location of a particular pillar in the bottom stack. However, the reflected illumination light from the bottom stack can include information about the bottom stack pillars that includes a tilt signature, which can make it difficult to determine the exact location of, e.g., the exact location of a top of the particular pillar in the bottom stack. That is, the tilt signature comprises a portion of the illumination light reflected by the imperfect pillars in the lower layers of the wafer and makes it difficult to align pillars in the upper layers with the pillars in the lower layers.

A tilt signature from a NAND pillar can be particularly problematic when the substrate stack is relatively transparent. For example, light from the alignment system can use visible to Infrared (VIS-IR) wavelengths that may penetrate deeply into or through a dielectric and nitride stack. As a result, the returned or observed light can include information about more or all of the tilt signature, thereby making it difficult to locate coordinates of the true or actual top of a particular pillar.

One solution to improve determination of pillar location or to reduce the influence of pillar tilt can include or use a pillar cap or alignment mark. In an example, pillar caps, alignment or overlay marks, or other features can be located at the top of one or more of the pillars in the first stack or bottom stack (such as first stack 100 discussed below), to help identify locations of the pillars in the first stack and thereby aid alignment with the pillars etched in the second or top stack (such as second stack 102 discussed below). The pillar alignment marks can be a block, plug, or the like, of an oxide or other material, located at the top of or directly above respective pillars in the first stack. A pillar alignment mark can include a material such as polysilicon or tungsten (or any similar material or dielectric capable of blocking light) that is provided at a pillar top to enhance visibility of the pillar. Such marks can increase an opacity of the stack and block light returned from the tilted pillars. Such a system is not entirely effective in blocking the tilt signature, however, especially when using diffraction-based alignment systems. For example, polysilicone can blend in with the substrate and oxide pillar caps making the pillar alignment marks difficult to distinguish. Alternatively, a material such as tungsten can provide greater contrast from the substrate but can be expensive and more difficult to use.

The present inventors have recognized, among other things, that an opaque hardmask film can be used as a tunable filter to help reduce or remove a tilt signature from being sensed by an alignment system. That is, a portion of alignment system illumination light returned or sensed by the system can omit information about a tilt signature when particular wavelengths of illumination light are filtered out. In an example, the solution can include or use a first hardmask layer having a first depth or thickness (e.g., a partial thickness), T_{PH}, deposited on a top stack of alternating nitride and oxide layers. At this stage, pillars are not yet formed in the top stack, but pillars are formed in a bottom stack under the top stack. One or more embedded or topographical alignment marks can be formed in the first hardmask layer, such as in alignment with pillar alignment marks or oxide caps corresponding to respective pillars on the lower stack. A thickness of the first hardmask layer can be sufficient to filter out or impede particular wavelengths of illumination light from the alignment system without impeding other wavelengths that can penetrate the first hardmask layer and impinge on the pillar alignment marks or oxide caps corresponding to the pillars in the bottom stack.

A second hardmask layer having a second depth or thickness (e.g., a second partial-thickness, which may be different from the first partial-thickness) can be deposited on or above the first hardmask layer to form a total-thickness hardmask layer having a depth or thickness T_{TOTAL}. The total-thickness hardmask layer can completely block the illumination light return so that the pillar tilt cannot be seen by the alignment systems scanner. However, the topographical marks or other alignment marks formed in the first hardmask layer can be used or propagated up through the second hardmask layer. Accordingly, subsequent masking layers or etch steps can be used to form pillars in the top stack in alignment with corresponding pillars in the bottom stack. The hardmask thickness and/or opacity can be selected or designed such that a desired wavelength of the alignment system can be used to locate the pillars in the bottom stack, while undesired wavelengths that carry information about pillar tilt can be filtered out.

The total-thickness hardmask layer formed by the combination of the first and second hardmask layers can be defined by, for example, dry etch requirements of the semiconductor device being fabricated. Instead of forming topology-based marks on the tier stack (e.g., directly on the decks or substrate stacks), topographical marks formed in a hardmask layer can be removed and thus can be sacrificial marks. Advantages to the systems and methods described herein can include cost savings as there is generally no additional processing cost for forming topographical marks in a hardmask layer. While particular examples of the systems and methods described in this disclosure refer to pillar overlay in stacked NAND structures, the solutions described herein can be similarly applied to any type of semiconductor fabrication that employs an opaque hardmask or risks inaccurate alignment of layers or structures, such as due to substrate transparency or processing variations.

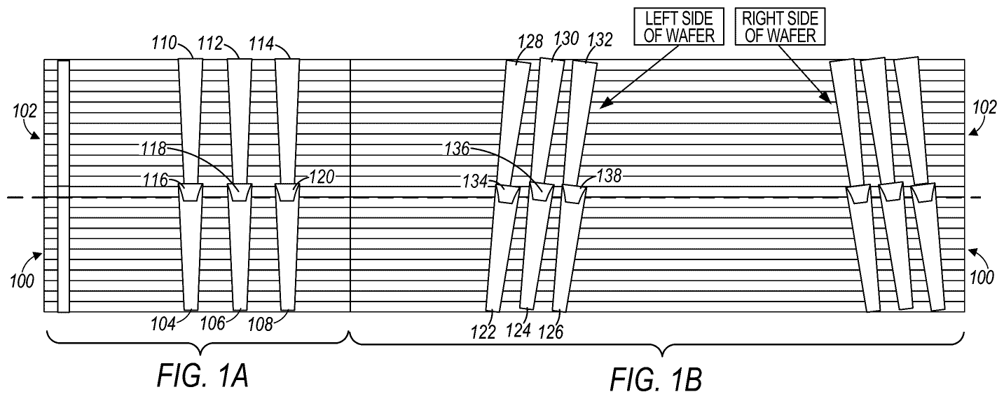

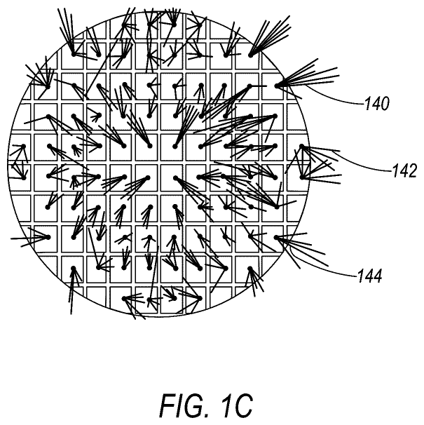

FIG. 1A illustrates generally an example of ideal pillar alignment in multiple stacks of a three-dimensional (3D) NAND memory structure. FIG. 1B illustrates generally an example of aligned but tilted pillar structures in multiple stacks of a 3D NAND memory structure.

FIG. 1A shows a cross-section of a stacked substrate, comprising a first stack 100 and a second stack 102. In an example, the first stack 100 can be a lower or bottom stack and the second stack 102 can be an upper or top stack, such as located above and adjacent to the lower stack. Each of the first stack 100 and/or the second stack 102 can be formed by alternating layers of an oxide material, such as silicon oxide, and a nitride material, such as silicon nitride. In an example, each layer can be formed from a single material, such as an oxide material or a nitride material. In another example, the first stack 100 and the second stack 102 can be formed from different materials. The stacked substrate can be formed from any suitable or appropriate material as desired.

In the example of FIG. 1A, pillars are formed in or through all or a portion of the stacks. For example, a first pillar 104, a second pillar 106, and a third pillar 108, can be formed in the first stack 100. Similarly, a fourth pillar 110, a fifth pillar 112, and a sixth pillar 114, can be formed in the second stack 102. In an example particular to fabrication of 3D NAND devices, alignment of corresponding pillars in adjacent stacks is important to ensure high yield and density. Ideally, the pillars in each stack are aligned as illustrated in FIG. 1A, such that pillars in the second stack 102 align vertically with corresponding pillars in the first stack 100. For example, in an ideal device, the fourth pillar 110 is perfectly vertically formed and aligned with the first pillar 104 which is also perfectly vertically formed. That is, a bottom of the fourth pillar 110 would be located directly above and aligned vertically with a top of the first pillar 104. In practice, however, alignment between pillars of adjacent stacks can be challenging due to the contribution of several systematic and random sources of variation, such as arising from etching processes (e.g., tilt and twist), inaccuracies in photolithographic processing, and film processing (bending, in-plane distortion), etc. One significant systematic source of variation is pillar tilt, an example of which is shown in FIG. 1B. Pillar tilt is produced during the etching process due, in part, to the localized plasma gradient in the etch chamber when pillars are formed. Different pillars in the same wafer can exhibit differences in the magnitude and direction of tilt.

As illustrated in FIG. 1B, as the wafers are fabricated, the tilted pillars may lead to alignment errors. For example, because a portion of alignment system illumination light can be reflected from the tilted pillars in the first stack 100, subsequent steps may cause pillars to be etched in incorrect positions in the second stack 102. For example, as shown in FIG. 1B, the bottom of a tilted second stack pillar 128 is displaced (e.g., laterally) with respect to the top of a corresponding tilted first stack pillar 122. Similarly, the bottom of pillar 130 is displaced with respect to the top of pillar 124, and the bottom of pillar 132 is displaced with respect to the top of pillar 126.

In an example, pillar caps, alignment or overlay marks, or other features can be located at the top of one or more of the pillars in the first stack 100, to help identify locations of the pillars in the first stack 100 and thereby aid alignment with the pillars etched in the second stack 102. The pillar alignment marks can be a block, plug, or the like, of an oxide or other material, located at the top of or directly above respective pillars in the first stack 100. For example, a first pillar alignment mark 116 can be located at, near, or proximate a top portion of the first pillar 104.

Displacement or tilt of pillars can be different or can vary at different parts of the wafer. For example, the bottom of pillar 128 can be located on a different portion of pillar alignment mark 134 located above pillar 122 than the bottom of pillar 130 is on pillar alignment mark 136 located above pillar 124. In an example, when an alignment system scanner attempts to identify a location of alignment mark 134, such as to identify pillar 122 and thus a location in which to form pillar 128 in the second stack, the scanner can identify a cross-wafer signature as illustrated in FIG. 1C, in which signatures 140, 142, and 144, reflected from the pillars in the first stack 100 may not definitively indicate a specific pillar location. Instead, the signatures indicate a structure with lean or tilt at indeterminate angles and directions. The cross-wafer signature can be a significant issue because the oxide-nitride-oxide-nitride (ONON) layers forming the first stack 100 are relatively transparent, which can cause the visible and/or infrared wavelengths of the alignment system to penetrate deeper into the stack.

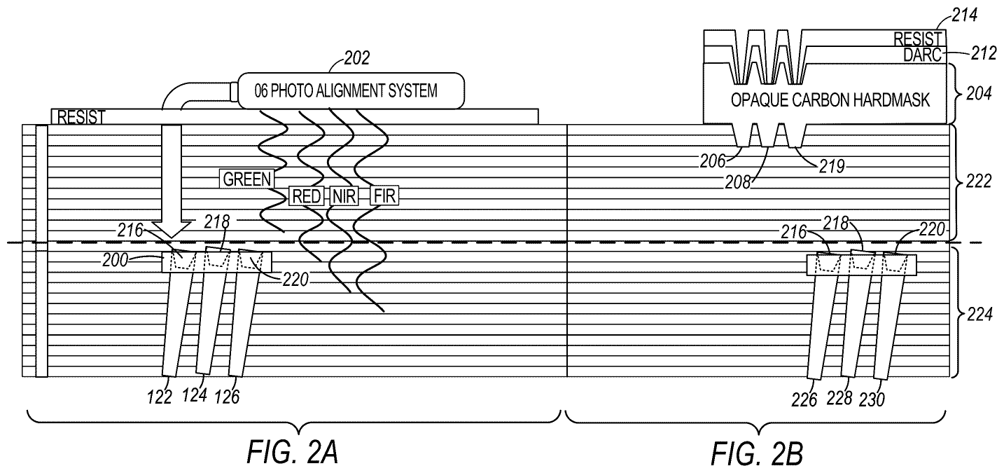

FIG. 2A illustrates generally an example of a photoalignment system used to locate embedded structures. FIG. 2B illustrates generally an example of a hardmask layer disposed over embedded pillar structures.

In the example illustrated in FIG. 2A, a polysilicon sheet 200 (or a sheet made of tungsten or any similar material or dielectric material capable of blocking light) can be located over, above, on top of, or the like, the pillar alignment marks 216, 218, and 220 in a first stack 100 (e.g., a bottom stack, lower stack, etc.). The polysilicon sheet 200 can increase the opacity of a portion of the first stack 224 to aid in blocking or reducing unwanted or unnecessary light being reflected from the tilted pillars 226, 228, and 230. The polysilicon sheet 200, by itself, is not completely effective in blocking the tilt signature because the polysilicon sheet 200 is only partially opaque relative to the stack layers and the pillar alignment marks. Thus, the polysilicon sheet 200 at least partially blends in with the layers and the pillar alignment marks. This is especially true when the photo alignment system 202 is a diffraction-based system in which light of multiple different wavelengths (e.g., green, red, near infrared, far infrared, etc.) are used because different wavelengths penetrate deeper into the stack than others, and different aspects or portions of the pillars are captured by the different wavelengths. Further compounding the issue is that light having smaller wavelengths (e.g., green light) does not capture as much pillar tilt information but can be more sensitive to process variations. On the other hand, light having longer wavelengths (e.g., far infrared) can be less sensitive to process variations but can capture more information about pillar tilt.

Another method used for feature alignment is illustrated in FIG. 2B. In an example, a first step can include forming topographical alignment marks 206, 208, and 210 in a second stack 222 (e.g., a top stack, upper stack, etc.). The locations of the topographical marks can be based on, e.g., the sensed or measured location of the pillar alignment marks 216, 218, and 220, such as according to the example of FIG. 2A. For the above-described reasons, the exact locations of the pillar alignment marks may be indeterminate due to pillar tilt signatures, so the topographical marks may not be sufficiently accurate. In this example, a second step can include depositing an opaque hardmask 204 above, on top of, or the like, the second stack 102. Using a full-thickness hardmask 204, having a depth or thickness Tₜₒₜₐₗ, however, can completely block light from the alignment system from reaching the first stack 224. Accordingly, none of the alignment system illumination light is reflected and available to help locate the pillar alignment marks, 216, 218, and 220. In this example, the alignment marks 206, 208, and 210 cap propagate up through the hardmask. For example, additional or subsequent layers can be deposited over the full-thickness hardmask 204, such as a dielectric anti-reflective coating (DARC) layer 212 and/or a photoresist layer 214 (collectively “additional layers”), and the first alignment marks 206, 208, and 210, can propagate up through the additional layers such that a top surface of the additional layers includes topographical alignment marks that correspond to the earlier-formed topographical alignment marks 206, 208, and 210 formed in the full-thickness hardmask layer 204. However, the utility of the alignment marks is compromised because their respective locations is based on insufficiently accurate information about the locations of the underlying pillars in the first stack 224.

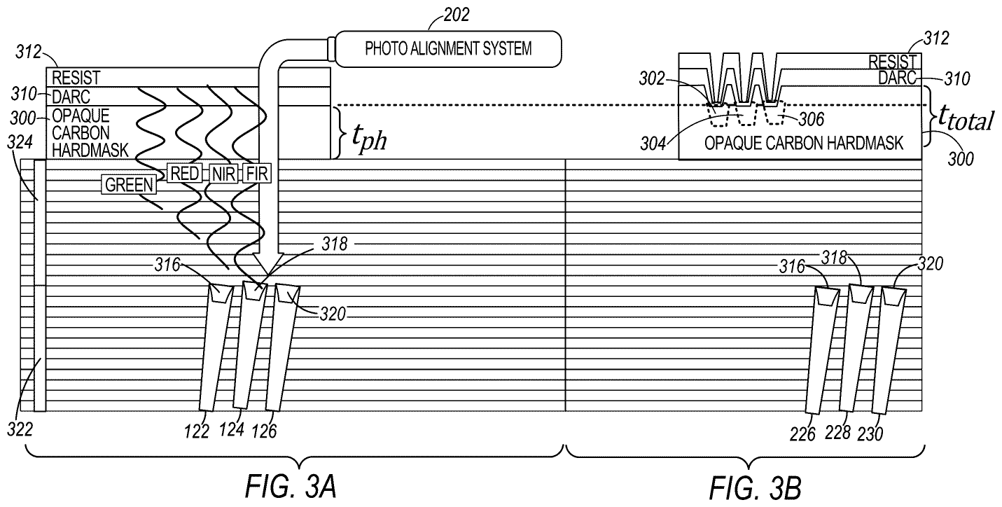

The present inventors have recognized that a solution to the alignment problem can include or use a hardmask with selective opacity. That is, the solution can include or use a masking layer that is configured to block particular wavelengths of illumination light. In some examples, the solution includes applying multiple different layers of hardmask with respective different opacity characteristic. FIGS. 3A-3B illustrate generally an example that can include using a photoalignment system to locate embedded structures, such as NAND pillars, using illumination light that is at least partially blocked or filtered by a hardmask layer. FIG. 3A illustrates an example of a the photoalignment system used to locate embedded structures through a first masking layer. FIG. 3B illustrates generally an example of a patterned masking layer that is registered to one or more embedded structures. In an example, the first masking layer can be a hardmask configured to block at least a portion of light in the visible spectrum (e.g., a 532 nm green wavelength, a 633 nm red wavelength, or any wavelength in the visible spectrum desired to be blocked or filtered). The first masking layer can also be a hardmask layer configured to block at least a portion of light in a near-infrared region (e.g., at or around 775 nm wavelength) or to block at least a portion of light in a far-infrared region (e.g., at or around 850 nm wavelength). Thus, an opaque layer such as the first masking layer can block light at smaller or smaller wavelengths from reaching alignment marks buried in the stack and can allow light at larger wavelengths to reach the alignment marks, which can provide a more reliable signal than light at smaller wavelengths.

FIGS. 3A and 3B illustrate cross-sections of a substrate stack, including the first stack 322 and the second stack 324. In a first step of an alignment process flow, a first partial-thickness hardmask 300 (e.g., an opaque carbon hardmask), having a thickness T_{PH} can be located, deposited, or the like above or on top of the second stack 324. This partial-thickness depth of the hardmask, or one or more other properties of the hardmask, can be selected such that the hardmask 300 filters out or impedes transmission of particular wavelengths of light. The hardmask 300 is configured to admit or allow other wavelengths to pass, to thereby allow the scanner of the photo alignment system 202 to penetrate the hardmask and receive reflected information about locations of the pillar alignment marks 316, 318, and 320. The process flow can optionally include depositing additional layers such as a DARC layer 310 and/or a resist layer 312 above the first partial-thickness hardmask 300.

In a second step of the alignment process flow, first topographical alignment marks 302, 304, 306 can be formed in the first partial-thickness hardmask 300, such as at a top portion of the partial-thickness hardmask 300. The formed topographical alignment marks 302, 304, and 306 can be registered or aligned with the pillar alignment marks 316, 318, and 320 in the first stack 322. In a third step of the alignment process flow, a second partial-thickness hardmask 308 can be deposited above the first partial thickness hardmask 300. In an example, the second partial-thickness hardmask 308 can have a second thickness T_{PH2} such that when added together, the thickness of the first partial-thickness hardmask 300 and the second partial-thickness hardmask 308 equals the thickness of the full-thickness hardmask 204, discussed above (T_{PH}+T_{PH}2=T_{TOTAL}). The total thickness (T_{TOTAL}) can again depend on or be defined by the dry etch requirements of the particular device being fabricated. For example, the total thickness can range from approximately 36 kilo-Angstroms (kA) to 42 kA of carbon. The total thickness can be above or below the example range as desired or appropriate. In an example, the combination of the hardmask layers 300 and 308 can impede all light from the photo alignment system 202 from penetrating the stacks and locating pillars or pillar features in the first stack 322. However, the topographical alignment marks 302, 304, and 306 are registered to the pillars, as previously described, and processing can continue, such as to form pillars in the second stack 324.

The alignment marks 302, 304, 306 can propagate up through the hardmask layers (e.g., comprising a DARC layer and/or a resist layer) such that a top surface of the workpiece includes topographical alignment marks that correspond to the first topographical alignment marks 302, 304, 306 and are therefore aligned with the pillar alignment marks 316, 318, and 320 in the first stack 100. In an example, a top-most resist layer 312 can be patterned and used, for example, in subsequent processing steps for etching the second stack 324 and/or one or more layers disposed thereon. In an example, features in the resist layer 312 can be defined or positioned based on the location of the topographical features in the top-most layer (e.g., the second stack 324). In an example, the first topographical alignment marks 302, 304, 306 can be protected by the additional layers (e.g., the resist layer 312) from an etchant or from other photolithographic processes and, accordingly, artifacts of the alignment marks 302, 304, 306 may not be transferred to the substrate 322 in some examples.

In a further subsequent processing step, at least a portion of the hardmask layers and the topographical alignment marks (e.g., topographical alignment marks 302, 304, 306) formed in the layers can be removed. Thus, a hardmask can be provided in multiple steps and characteristics of the hardmask can be leveraged as a tunable filter to reduce or remove information about a tilt signature from pillars in a lower stack, which may be otherwise difficult to locate. Accordingly, the present systems and methods can be used for more efficient and precise fabrication of aligned structures, such as pillars in stacked NAND stacks. In various examples, the hardmask layer(s) and the topographical alignment marks can be removed during subsequent processing of the wafer.

The thickness of the combined hardmask layers can be totally or completely opaque or nearly completely opaque such that a photoalignment signal is impeded by the hardmask and may not be used to locate the embedded reference features. However, information about the spatial relationship between the alignment marks (e.g., as propagated up through the hardmask layers) and the embedded reference features (e.g., the pillar alignment marks) can be used for alignment of subsequent layers or processes. Thus, the topographical alignment marks can be used to align and pattern any subsequent layers as the process is repeated until the wafer is fully fabricated.

While the examples discussed herein are in the context of fabrication of structures of a 3D NAND memory, the techniques discussed in the present disclosure can be applied to the fabrication of any similar semiconductor device. Also, the dual stack substrate can include reference marks and/or features that can correspond to, for example, passive or active circuit elements or other fiducial features.

Advantages to using a multiple-step deposition of hardmask include cost savings as there is no added cost for forming topographical marks in the hardmask layers. Additionally, the thickness and thus the opacity of the hardmask layers can be designed such as to allow light of one or more desired wavelengths to pass through it while filtering out undesired wavelengths. In an example, an opacity of a hardmask can be tuned or changed by, for example, varying a boron concentration in the hardmask and/or adjusting a carbon deposition temperature. Other material or process variations can be similarly leveraged to change light transmissivity or opacity characteristics of a hardmask layer.

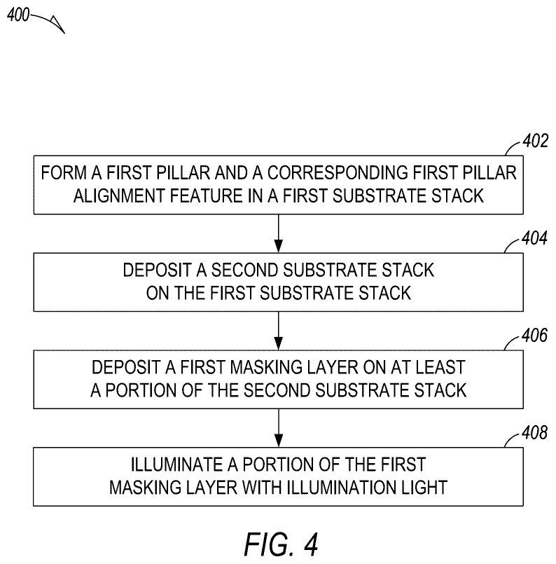

FIG. 4 illustrates generally an example of a method 400 that includes or uses an at least partially opaque hardmask layer to filter light from a photoalignment system. At operation 402, the method 400 can include forming a first pillar and a corresponding first pillar alignment feature in at least a portion of a first substrate stack. In an example, the first substrate stack can comprise alternating layers of a nitride material, such as silicon-nitride, and an oxide material, such as silicon-dioxide. In an example, one layer of the stack can be a conductive layer and the other layer of the stack can be an insulating layer. In an example, the pillar can be formed at operation 402 by etching a hole in the stack layers and then filling the hole with material such as an oxide, a nitride, and/or a polysilicon.

At operation 404, the method 400 can include depositing a second substrate stack on the first substrate stack. In an example, the second substrate stack can be formed by depositing alternating layers of the same or similar oxide-nitride materials that comprise the first substrate stack. In another example, the second substrate stack can be formed from a single material, different from the oxide-nitride stack of the first substrate stack, as appropriate or desired.

At operation 406, the method 400 can include depositing a first masking layer on at least a portion of the second substrate stack. In an example, the first masking layer can include an opaque or semi-opaque (e.g., to particular wavelengths of light) hardmask layer that can be formed from at least one of amorphous carbon, an organo siloxane material, SiN, SiON, TiN, tungsten, or a combination thereof, among other materials. The first masking layer can be deposited on the substrate by chemical vapor deposition (CVD), physical vapor deposition (PVD), or spin coating (spin-on), or using another process or technique.

At operation 408, the method 400 can include illuminating a portion of the first masking layer with illumination light from a photoalignment system. In an example, a reflected portion of the illumination light indicates a location of the first pillar alignment feature corresponding to the first pillar (e.g., as formed at operation 402). In such an example, the first masking layer can block at least a portion of the illumination light from reaching the first or second substrate stacks or can block a reflected portion of the illumination light, such as would otherwise indicate a tilt signature from the first pillar. In an example, particular wavelengths of the illumination light (undesired wavelengths) can be blocked by the first masking layer, while other wavelengths (desired wavelengths) can pass through the first masking layer.

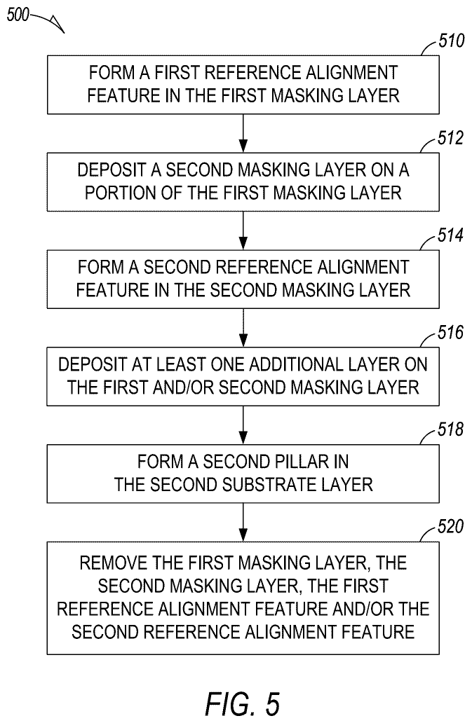

FIG. 5 illustrates generally an example of a method 500 that includes or uses topographical marks in hardmask layers with pillar alignment features to align pillars of a three-dimensional (3D) NAND memory assembly. The example of FIG. 5 can include operations 402-408 from the example of FIG. 4, for example preceding operation 510.

At operation 510, the method 500 can include forming a first reference alignment feature in the first masking layer (such as the first masking layer deposited at operation 406). In an example, the first reference alignment feature can be deposited on the first masking layer as a portion of a new film deposition process (e.g., by depositing a layer of film on top of the first masking layer) or can be formed as a portion of the same process used to form the first masking layer (e.g., by etching the first masking layer), such that the first reference alignment feature is registered or aligned with respect to the corresponding first pillar alignment feature. In an example, the first reference alignment feature is a topographical alignment feature that is etched in the first masking layer.

At operation 512, the method 500 can include depositing a second masking layer on at least a portion of the first masking layer. The second masking layer can be an opaque or semi-opaque hardmask layer that can be formed from at least one of amorphous carbon, an organo siloxane material, SiN, SiON, TiN, tungsten, or a combination thereof, among other materials. The second masking layer can comprise the same or different material as the first masking layer. The second masking layer can be deposited on the first masking layer by chemical vapor deposition (CVD), physical vapor deposition (PVD), or spin coating (spin-on), or using another process or technique. Thus, the first masking layer can be a first partial-thickness layer of a hardmask, and the second masking layer can be a second partial-thickness layer of hardmask. The total thickness of the two masking layers can be a total-thickness or full-thickness hardmask, the thickness of which can be based on, for example, the dry etch requirements of the 3D NAND memory being fabricated. In an example, as the thickness of the stack increases with each NAND node, the thickness of the carbon hardmask can correspondingly increase.

At operation 514, the method 500 can include forming a second reference alignment feature in the second masking layer. For example, operation 514 can include illuminating a portion of the second masking layer with the illumination light and aligning the second reference alignment feature with the first reference alignment feature, which in turn is aligned with the first pillar alignment feature. In an example, the second reference alignment feature can be deposited on the second masking layer as a portion of a new film deposition process (e.g., by depositing a layer of film on top of the first masking layer) or can be formed as a portion of the same process used to form the second masking layer (e.g., by etching the second masking layer), such that the second reference alignment feature is registered or aligned with respect to the first reference alignment feature and/or with respect to the corresponding first pillar alignment feature. In another example, the second reference alignment feature may be aligned with respect to other features in the substrate stacks such as passive or active circuit elements or other fiducial features.

At operation 516, the method 500 can include depositing at least one additional layer on at least one of the first masking layer or the second masking layer. The additional layer can include, for example, a dielectric anti-reflective coating (DARC) layer, a photoresist layer, or the like.

In an example, the additional layers can be patterned and used in subsequent processing steps for etching the second substrate layer and/or one or more layers deposited on the second substrate layer. Features in the resist layer can be defined or positioned based on the location of topographical features in the substrate stacks or the masking layers. For example, the reference alignment features in the first masking layer and/or the second masking layer can propagate up to the resist layer, to a DARC layer, or to any other additional layer.

At operation 518, the method 500 can include forming a second pillar in the second substrate layer. The second pillar can be formed in substantially the same manner as discussed above, such as by etching through a top stack toward a first pillar in a bottom stack. Forming the second pillar can include or use at least one of the first reference alignment feature or the second reference alignment feature, such that a bottom of the second pillar is located at the first pillar alignment feature (e.g., above or on top of the first pillar alignment feature).

At operation 520, the method can include removing at least one of the first masking layer, the second masking layer, the first reference alignment feature, or the second reference alignment feature. In an example, the first masking layer and/or the second masking layer can be sacrificial layers and the alignment marks in those layers can be removed during a subsequent processing step, for example, after the second pillar in the second substrate layer is formed.

Some example benefits of the systems and methods described herein include more flexibility in the placement of alignment marks on or in a wafer. For example, using the techniques discussed herein, alignment marks may be unrestricted to scribe line areas and accordingly may not be subject to decreasing scribe width. In some examples, alignment marks can be placed in the die or substrate at locations that are more representative for overlay accuracy, for example, because the mark locations can correspond to locations of the pillars, circuit components, or other features of the wafer or semiconductor.

### Additional Notes & Examples

Various aspects of the present disclosure can help provide a solution to the pillar tilt problems discussed herein. For example, Example 1 is a three-dimensional (3D) NAND structure, comprising: a first substrate stack comprising alternating oxide and nitride layers; a plurality of first pillars formed through multiple layers of the first substrate stack; a plurality of first pillar alignment features respectively provided at top portions of the plurality of first pillars; a second substrate stack provided on the first substrate stack, the second substrate stack comprising alternating oxide and nitride layers, and the second substrate stack covering the plurality of first pillars and the plurality of first pillar alignment features; and a plurality of second pillars formed through multiple layers of the second substrate stack, wherein bottoms of each of the second pillars are respectively aligned with corresponding ones of the first pillar alignment features.

In Example 2, the subject matter of Example 1 optionally includes wherein the first pillar alignment features comprise oxide plugs.

In Example 3, the subject matter of Example 2 optionally includes a first masking layer deposited on at least a portion of the second substrate stack; and a first reference alignment feature formed in the first masking layer and aligned with one or more of the first pillar alignment features.

In Example 4, the subject matter of Example 3 optionally includes wherein the first reference alignment feature is a topographical alignment feature in the first masking layer.

In Example 5, the subject matter of any one or more of Examples 3-4 optionally include a second masking layer deposited on at least a portion of the first masking layer, wherein the second masking layer includes a second reference alignment feature aligned with the first reference alignment feature, wherein features of the second masking layer correspond to etch locations for the plurality of second pillars.

In Example 6, the subject matter of any one or more of Examples 3-5 optionally include wherein the first masking layer is a hardmask layer configured to block at least a portion of light in the visible spectrum, and wherein the portion of light in the visible spectrum includes light having wavelengths at or near 532 nm or 633 nm.

In Example 7, the subject matter of any one or more of Examples 3-6 optionally include wherein the first masking layer is a hardmask layer configured to block at least a portion of light in a near-infrared region, wherein the portion of light in the near-infrared region includes light having wavelengths at or near 775 nm.

In Example 8, the subject matter of any one or more of Examples 3-7 optionally include wherein the first masking layer is a hardmask layer configured to block at least a portion of light in a far-infrared region, and wherein the portion of light in the far-infrared wavelength includes light having wavelengths at or near 850 nm.

In Example 9, the subject matter of any one or more of Examples 3-8 optionally include wherein the first reference alignment feature is a sacrificial alignment feature, and wherein the first masking layer is a sacrificial layer.

Example 10 is a method of aligning pillars of a three-dimensional (3D) NAND memory assembly, the method comprising: forming a first pillar and a corresponding first pillar alignment feature in at least a portion of a first substrate stack comprising alternating oxide and nitride layers; depositing a second substrate stack on the first substrate stack, the second substrate stack covering the first pillar alignment feature and the first pillar; depositing a first masking layer on at least a portion of the second substrate stack; and illuminating a portion of the first masking layer with illumination light, wherein a reflected portion of the illumination light indicates a location of the first pillar alignment feature corresponding to the first pillar, wherein particular wavelengths of the illumination light are blocked by the first masking layer.

In Example 11, the subject matter of Example 10 optionally includes forming a second pillar through at least a portion of the second substrate stack, wherein a bottom portion of the second pillar coincides with the location of the first pillar alignment feature.

In Example 12, the subject matter of any one or more of Examples 10-11 optionally include wherein the first masking layer is a hardmask layer that blocks at least a portion of a tilt signature of the first pillar, wherein the tilt signature comprises a portion of the illumination light reflected by the first pillar.

In Example 13, the subject matter of any one or more of Examples 10-12 optionally include forming a first reference alignment feature in the first masking layer, wherein the first reference alignment feature is a sacrificial alignment feature, and wherein the first masking layer is a sacrificial layer.

In Example 14, the subject matter of Example 13 optionally includes wherein a location of the first reference alignment feature corresponds to a location of the first pillar alignment feature in the first substrate stack.

In Example 15, the subject matter of any one or more of Examples 13-14 optionally include depositing a second masking layer on at least a portion of the first masking layer; forming a second reference alignment feature in the second masking layer, wherein the second reference alignment feature is aligned with the first reference alignment feature; and forming a second pillar in the second substrate layer using at least one of the first reference alignment feature or the second reference alignment feature such that a bottom of the second pillar is located at the first pillar alignment feature.

In Example 16, the subject matter of Example 15 optionally includes removing the first masking layer, the second masking layer, and the first reference alignment feature.

In Example 17, the subject matter of any one or more of Examples 15-16 optionally include depositing at least one of a dielectric anti-reflective coating (DARC) layer or a photoresist layer on at least one of the first masking layer or the second masking layer to define an etch pattern for one or more pillars to be formed in the second substrate stack.

In Example 18, the subject matter of any one or more of Examples 1-17 optionally include wherein the first substrate stack and the second substrate stack are formed using alternating layers of nitride and oxide material.

Example 19 is a method of aligning pillars of a three-dimensional (3D) NAND memory assembly, the method comprising: forming a first pillar and a corresponding first pillar alignment feature in at least a portion of a first substrate stack; depositing a second substrate stack on the first substrate stack, the second substrate stack covering the first pillar alignment feature and the first pillar; depositing a first masking layer on at least a portion of the second substrate stack; illuminating a portion of the first masking layer with illumination light, wherein a reflected portion of the illumination light indicates a location of the first pillar alignment feature corresponding to the first pillar, wherein particular wavelengths of the illumination light are blocked by the first masking layer; forming a first reference alignment feature in the first masking layer; using the light source to align the first reference alignment feature with the first pillar alignment feature; depositing a second masking layer on at least a portion of the first masking layer; forming a second reference alignment feature in the second masking layer, wherein the second reference alignment feature is aligned with the first reference alignment feature; forming a second pillar in the second substrate layer using at least one of the first reference alignment feature or the second reference alignment feature such that a bottom of the second pillar is located at the first pillar alignment feature; depositing at least one of a dielectric anti-reflective coating (DARC) layer or a photoresist layer on at least one of the first masking layer or the second masking layer; and removing at least one of the first masking layer, the second masking layer, the first reference alignment feature, or the second reference alignment feature.

In Example 20, the subject matter of Example 19 optionally includes wherein the first masking layer and the second masking layer are hardmask layers that block at least a portion of a tilt signature of the first pillar, wherein the tilt signature comprises illumination light reflected by the first pillar, wherein the first reference alignment feature and the second reference alignment feature are sacrificial alignment features, and wherein the first masking layer and the second masking layer are sacrificial layers.

Each of these non-limiting numerical Examples can stand on its own or can be combined in various permutations or combinations with one or more of the other Examples, or with other examples or features discussed elsewhere herein.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the embodiments should be determined with reference to the appended claims, along with the full scope of equivalents to which such claims are entitled.

What is claimed is:

1. A three-dimensional (3D) NAND structure, comprising:
a first substrate stack comprising alternating oxide and nitride layers;
a plurality of first pillars formed through multiple layers of the first substrate stack;
a plurality of first pillar alignment features respectively provided at top portions of the plurality of first pillars;
a second substrate stack provided on the first substrate stack, the second substrate stack comprising alternating oxide and nitride layers, and the second substrate stack covering the plurality of first pillars and the plurality of first pillar alignment features; and
a plurality of second pillars formed through multiple layers of the second substrate stack, wherein bottoms of each of the second pillars are respectively aligned with corresponding ones of the first pillar alignment features.

2. The 3D NAND structure of claim 1, wherein the first pillar alignment features comprise oxide plugs.

3. The 3D NAND structure of claim 2, comprising:
a first masking layer deposited on at least a portion of the second substrate stack; and
a first reference alignment feature formed in the first masking layer and aligned with one or more of the first pillar alignment features.

4. The 3D NAND structure of claim 3, wherein the first reference alignment feature is a topographical alignment feature in the first masking layer.

5. The 3D NAND structure of claim 3, comprising:
a second masking layer deposited on at least a portion of the first masking layer, wherein the second masking layer includes a second reference alignment feature aligned with the first reference alignment feature, wherein features of the second masking layer correspond to etch locations for the plurality of second pillars.

6. The 3D NAND structure of claim 3, wherein the first masking layer is a hardmask layer configured to block at least a portion of light in the visible spectrum, and wherein the portion of light in the visible spectrum includes light having wavelengths at or near 532 nm or 633 nm.

7. The 3D NAND structure of claim 3, wherein the first masking layer is a hardmask layer configured to block at least a portion of light in a near-infrared region, wherein the portion of light in the near-infrared region includes light having wavelengths at or near 775 nm.

8. The 3D NAND structure of claim 3, wherein the first masking layer is a hardmask layer configured to block at least a portion of light in a far-infrared region, and wherein the portion of light in the far-infrared wavelength includes light having wavelengths at or near 850 nm.

9. The 3D NAND structure of claim 3, wherein the first reference alignment feature is a sacrificial alignment feature, and wherein the first masking layer is a sacrificial layer.

10. A method of aligning pillars of a three-dimensional (3D) NAND memory assembly, the method comprising:
forming a first pillar and a corresponding first pillar alignment feature in at least a portion of a first substrate stack comprising alternating oxide and nitride layers;
depositing a second substrate stack on the first substrate stack, the second substrate stack covering the first pillar alignment feature and the first pillar;
depositing a first masking layer on at least a portion of the second substrate stack; and
illuminating a portion of the first masking layer with illumination light, wherein a reflected portion of the illumination light indicates a location of the first pillar alignment feature corresponding to the first pillar, wherein particular wavelengths of the illumination light are blocked by the first masking layer.

11. The method of claim 10, further comprising forming a second pillar through at least a portion of the second substrate stack, wherein a bottom portion of the second pillar coincides with the location of the first pillar alignment feature.

12. The method of claim 10, wherein the first masking layer is a hardmask layer that blocks at least a portion of a tilt signature of the first pillar, wherein the tilt signature comprises a portion of the illumination light reflected by the first pillar.

13. The method of claim 10, further comprising:
forming a first reference alignment feature in the first masking layer, wherein the first reference alignment feature is a sacrificial alignment feature, and wherein the first masking layer is a sacrificial layer.

14. The method of claim 13, wherein a location of the first reference alignment feature corresponds to a location of the first pillar alignment feature in the first substrate stack.

15. The method of claim 13, further comprising:
depositing a second masking layer on at least a portion of the first masking layer;
forming a second reference alignment feature in the second masking layer, wherein the second reference alignment feature is aligned with the first reference alignment feature; and
forming a second pillar in the second substrate layer using at least one of the first reference alignment feature or the second reference alignment feature such that a bottom of the second pillar is located at the first pillar alignment feature.

16. The method of claim 15, further comprising:
removing the first masking layer, the second masking layer, and the first reference alignment feature.

17. The method of claim 15, further comprising:
depositing at least one of a dielectric anti-reflective coating (DARC) layer or a photoresist layer on at least one of the first masking layer or the second masking layer to define an etch pattern for one or more pillars to be formed in the second substrate stack.

18. The method of claim 1, wherein the first substrate stack and the second substrate stack are formed using alternating layers of nitride and oxide material.

19. A method of aligning pillars of a three-dimensional (3D) NAND memory assembly, the method comprising:
forming a first pillar and a corresponding first pillar alignment feature in at least a portion of a first substrate stack;
depositing a second substrate stack on the first substrate stack, the second substrate stack covering the first pillar alignment feature and the first pillar;
depositing a first masking layer on at least a portion of the second substrate stack;
illuminating a portion of the first masking layer with illumination light, wherein a reflected portion of the illumination light indicates a location of the first pillar alignment feature corresponding to the first pillar, wherein particular wavelengths of the illumination light are blocked by the first masking layer;
forming a first reference alignment feature in the first masking layer;
using the light source to align the first reference alignment feature with the first pillar alignment feature;
depositing a second masking layer on at least a portion of the first masking layer;
forming a second reference alignment feature in the second masking layer, wherein the second reference alignment feature is aligned with the first reference alignment feature;
forming a second pillar in the second substrate layer using at least one of the first reference alignment feature or the second reference alignment feature such that a bottom of the second pillar is located at the first pillar alignment feature;
depositing at least one of a dielectric anti-reflective coating (DARC) layer or a photoresist layer on at least one of the first masking layer or the second masking layer; and
removing at least one of the first masking layer, the second masking layer, the first reference alignment feature, or the second reference alignment feature.

20. The method of claim 19, wherein the first masking layer and the second masking layer are hardmask layers that block at least a portion of a tilt signature of the first pillar, wherein the tilt signature comprises illumination light reflected by the first pillar, wherein the first reference alignment feature and the second reference alignment feature are sacrificial alignment features, and wherein the first masking layer and the second masking layer are sacrificial layers.
